(19) United States
(12) Patent Application Publication
(10) Pub. No.: US 2023/0209774 A1
(43) Pub. Date: Jun. 29, 2023

(54) APPARATUS AND SYSTEM FOR TWO-PHASE SERVER COOLING

(71) Applicant: Baidu USA LLC, Sunnyvale, CA (US)

(72) Inventor: Tianyi GAO, San Jose, CA (US)

(21) Appl. No.: 17/560,702

(22) Filed: Dec. 23, 2021

(51) Int. Cl. H05K 7/20

(52) U.S. Cl. CPC H05K 7/20309; H05K 7/20818; H05K 7/20318; H05K 7/20354; H05K 7/20327; H05K 7/20381

(57) ABSTRACT

Embodiments are disclosed of a cooling device. The cooling device includes a housing enclosing an internal volume, the housing having at least a heat transfer contact surface adapted to be thermally coupled to a heat-generating electronic component. A partition is positioned in the internal volume; the partition divides the internal volume into a liquid compartment and a vapor compartment, and the partition has a gap therein to allow fluid movement between the liquid compartment and the vapor compartment. A liquid inlet is fluidly coupled to the liquid compartment; a liquid outlet is fluidly coupled to the vapor compartment; and a vapor outlet is fluidly coupled to with the vapor compartment. Embodiments of cooling systems including design and operation using the cooling device are also disclosed.

### TECHNICAL FIELD

The disclosed embodiments relate generally to information technology (IT) liquid cooling systems, but not exclusively, to an apparatus and system for two-phase server cooling.

### BACKGROUND

Modern data centers like cloud computing centers house enormous amounts of information technology (IT) equipment such as servers, blade servers, routers, edge servers, power supply units (PSUs), battery backup units (BBUs), etc. These individual pieces of IT equipment are typically housed in racks within the computing center, with multiple pieces of IT equipment in each rack. The racks are typically grouped into clusters within the data center.

As IT equipment has become more computationally powerful it also consumes more electricity and, as a result, generates more heat. This heat must be removed from the IT equipment to keep it operating properly. Various cooling solutions have been developed to keep up with this increasing need for heat removal. One of the solutions is immersion cooling, and which the IT equipment is itself submerged in a cooling fluid. The cooling fluid can be a single-phase or two-phase cooling fluid; in either case, heat from the IT equipment is transferred into the cooling fluid in which it is submerged. But existing single-phase immersion systems only consider rack-level fluid recirculation without any local cooling acceleration. Current immersion cooling solutions, single-phase or two-phase, do not sufficiently support high power density servers which include one or more high power-density chips.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIGS. 1A-1B are cross-sectional views of an embodiment of an evaporator. FIG. 1A shows its construction and FIG. 1B shows an embodiment of its operation.

FIG. 2 is a schematic drawing of an embodiment of an information technology (IT) cooling system.

FIG. 3 is a schematic drawing of another embodiment of an information technology (IT) cooling system.

FIG. 4 is a schematic drawing of yet another embodiment of an information technology (IT) cooling system.

### DETAILED DESCRIPTION

Embodiments are described of two-phase cooling systems for use with information technology (IT) equipment in a data center or an IT container such as an IT rack. Specific details are described to provide an understanding of the embodiments, but one skilled in the relevant art will recognize that the invention can be practiced without one or more of the described details or with other methods, components, materials, etc. In some instances, well-known structures, materials, or operations are not shown or described in detail but are nonetheless encompassed within the scope of the invention.

Reference throughout this specification to “one embodiment” or “an embodiment” means that a described feature, structure, or characteristic can be included in at least one described embodiment, so that appearances of “in one embodiment” or “in an embodiment” do not necessarily all refer to the same embodiment. Furthermore, the particular features, structures, or characteristics may be combined in any suitable manner in one or more embodiments. As used in this application, directional terms such as “front,” “rear,” “top,” “bottom,” “side,” “lateral,” “longitudinal,” etc., refer to the orientations of embodiments as they are presented in the drawings, but any directional term should not be interpreted to imply or require a particular orientation of the described embodiments when in actual use.

Embodiments are described below of an evaporator and a cooling system combining immersion and multi-phase cooling of information technology (IT) systems. The described embodiments can be used in data center and server cooling systems to improve heat removal and energy efficiency. In addition, the disclosed embodiments enable some or all of the following benefits:
Efficient thermal management of high power-density systems.
Management of non-uniform power densities.
Solving hot spot challenges.
Accommodating different server hardware and electronics components.
Efficiency fluid loss prevention.
High operation efficiency.
Ease of deployment, operation, and maintenance.
Good solution extensibility and resilience.

The described embodiments are of a device-level to system-level design for high power-density servers using multiple phase fluids and provide efficient fluid management within the full system.

The embodiments include an advanced cooling device—i.e., an evaporator—used for circulating two-phase cooling fluid to extract heat from electronics. The cooling device includes an internal feature for separation the vapor and liquid phases of the two-phase cooling fluid. The cooling device includes one inlet port and at least two outlet ports: the inlet port is designed for liquid, one outlet is designed for vapor, and the other outlet is designed for liquid. A system using the described cooling device includes a vapor recirculation loop and liquid recirculation loop. Each loop can be controlled with dedicated sensors. The liquid loop is controlled by pumps and sensors to ensure proper fluid flow through the cooling devices.

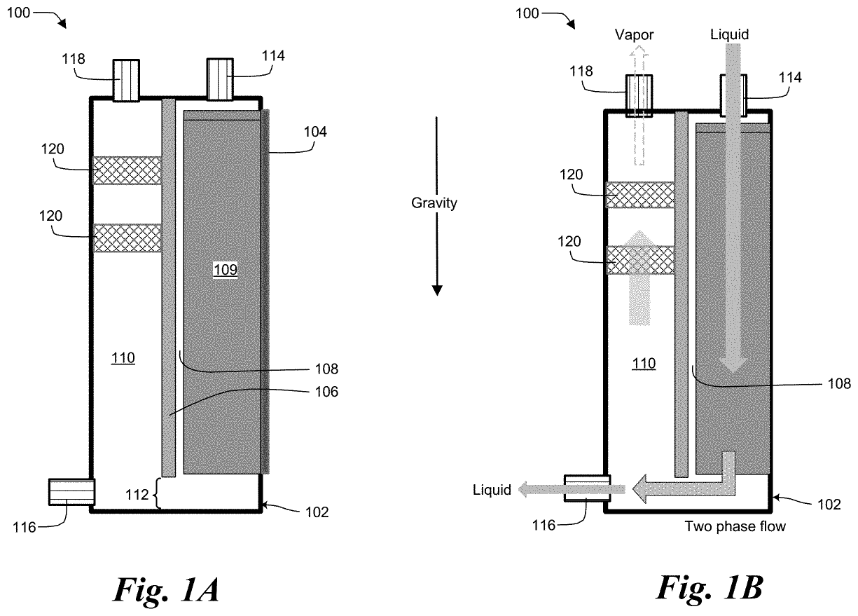

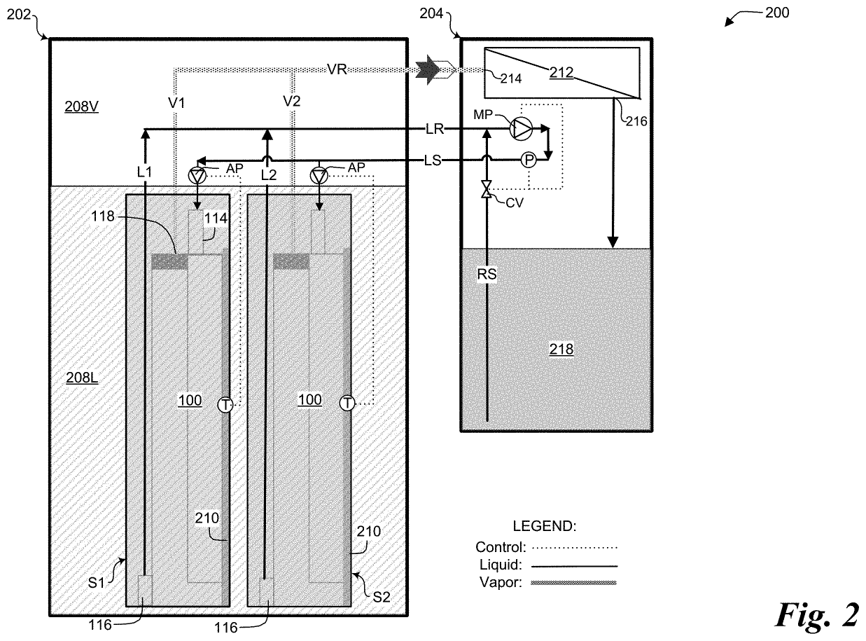

FIGS. 1A-1B together illustrate an embodiment of a cooling device 100. FIG. 1A illustrates its construction, FIG. 2B an embodiment of its operation. Embodiments of evaporator 100 can be used as part of a two-phase cooling loop in an IT cooling system (see, e.g., FIGS. 2 et seq.).

Evaporator 100 includes a housing 102 that encloses an internal volume. Housing 102 includes a heat transfer contact surface 104 that is adapted to be thermally coupled to one or more heat-generating electronic components in a piece of information technology (IT) equipment such as a server. In most embodiments, heat transfer contact surface 104 will be vertically-positioned surface (i.e., substantially parallel to gravity, as shown in the illustrated embodiment). A partition 106 divides the housing's internal volume into two compartments: a liquid compartment 108 and a vapor compartment 110. The liquid compartment is designed for heat extraction and the two-phase cooling fluid changes partially of fully to vapor in this region. The vapor compartment is designed to separate the vapor and any un-vaporized liquid of the two phase cooling fluid. In the illustrated embodiment, partition 106 is substantially parallel to heat transfer contract surface 104, but other embodiments partition 106 can be positioned and oriented differently than shown.

One or more heat-transfer fins 109 are positioned within liquid compartment 108 and thermally coupled to heat transfer contact surface 104, so that heat can flow from surface 104 into the heat-transfer fins. The heat transfer fins form flow channels through which the two-phase cooling fluid flows. One or more fluid filters 120 are positioned within vapor compartment 110 to separate liquid from vapor. The one or more fluid filters 120 increase the fluid flow resistance, so that the vapor phase naturally rises to the vapor outlet and the majority of the remaining liquid can be pumped away from the fluid outlet.

A gap 112 in partition 106 allows movement of fluid between the liquid and vapor compartments. In the illustrated embodiment gap 112 is positioned at the bottom of the internal volume of housing 102, but in other embodiments it can be positioned differently than shown. In various embodiments gap 112 can be a hole, multiple holes, a slot, or some other void or combination of voids that extends throughout the thickness of partition 106, thus allowing fluid to flow from one compartment to the other.

A liquid inlet 114 is positioned at the top of liquid compartment 108—i.e., at or near the highest point in the compartment—and a vapor outlet 118 is similarly positioned at the top of the vapor compartment. A liquid outlet 116 is positioned at or near the bottom of vapor compartment 110—i.e., at or near the lowest point in the compartment—so that liquid can flow out of the vapor compartment through the liquid outlet. The cooling device is packaged and used vertically, meaning that the fluid inlet and vapor outlet are positioned at the top and the liquid outlet is positioned at or near the bottom to enable the correct fluid flow. Liquid flow from the liquid inlet can benefit from gravity, and the vapor outlet can benefit from fluid separation as a result of rising vapor.

FIG. 1B illustrates an embodiment of the operation of cooling device 100. In operation, the liquid phase of a two-phase cooling fluid enters liquid compartment 108 through liquid inlet 114. Once in the liquid compartment, pressure at liquid inlet 114, and gravity, force the liquid phase over heat transfer fins 109. As the liquid phase flows over the heat-transfer fins it absorbs heat from the fins and changes from liquid phase to vapor phase. As the two-phase cooling fluid changes from liquid to vapor, the pressure at liquid inlet 114 and the force of gravity drive the vapor, and any liquid that has not been converted to vapor, toward the bottom of liquid compartment 108 where gap 112 is located. The vapor, and any un-vaporized liquid, then enter vapor compartment 110 through gap 112.

Depending for instance on how much heat is generated by the heat-generating component to which surface 104 is thermally coupled, the liquid phase flowing over heat-transfer fins 109 can be fully vaporized, so that only vapor enters vapor compartment 110 through gap 112, or can be less than fully vaporized, so that both liquid and vapor enter compartment 110 through gap 112. If only vapor enters vapor compartment 110, it flows upward through the vapor compartment and exits the cooling device through vapor outlet 118. Cooling device 100 is most efficient and effective if only vapor flows out through vapor outlet 118, so that one or more liquid filters 120 can be used to remove liquid that might be flowing upward through the vapor compartment 110 toward vapor inlet 118. If both vapor and liquid enter vapor compartment 110 through gap 112, the vapor flows upward through the compartment to vapor outlet 118, as described above. The liquid flowing into vapor compartment 110, mostly because of gravity, stays at or near the bottom of the vapor compartment and flows out of the vapor compartment through liquid outlet 116.

FIG. 2 schematically illustrates an embodiment of a two-phase cooling system 200. Cooling system 200 includes an information technology (IT) container 202 coupled to a cooling unit 204. IT container 202 is an immersion cooling container adapted to hold a cooling fluid 208. In the illustrated embodiment immersion cooling fluid 208 is a two-phase cooling fluid with a liquid phase 208L and a vapor phase 208V; liquid phase 208L occupies a lower portion of IT container 202, and in operation vapor phase 208V can exist in the part of IT container 202 above the liquid phase. In other embodiments, immersion cooling fluid 208 can be a single-phase cooling fluid. Generally, immersion cooling fluid 208 will be a dielectric fluid, meaning that it has little or no electrical conductivity.

In the illustrated embodiment, one or more servers S are submerged in the liquid phase 208L, and the amount or level of liquid phase 208L in IT container 202 is chosen so that servers S always remain fully submerged in the liquid phase. The illustrated embodiment includes two servers S1 and S2, but other embodiments can have more or less servers than shown. During operation of servers S, some of the heat generated by heat-generating components 210 within servers 206 can be transferred to liquid phase 208L, transforming it, by evaporation, into vapor phase 208V. Vapor phase 208V can rise into the space between a surface of the liquid phase 208L and the top of the IT container 202, where it condenses back into the liquid phase and, under the force of gravity, drops into the liquid phase 208L.

In addition to being immersion-cooled by immersion cooling fluid 208, one or more heat-generating components 210 within each server S are cooled by a two-phase cooling loop having a vapor loop and a liquid loop both of which circulate a two-phase cooling fluid 218. In an embodiment where immersion cooling fluid 208 is a two-phase fluid, the two-phase cooling fluid 218 flowing in the two-phase cooling loop can be the same as two-phase cooling fluid 208, but in other embodiments they need not be the same two-phase cooling fluid. Within each server, the heat-transfer contact surface 104 of a cooling device such as cooling device 100 shown in FIGS. 1A-1B is thermally coupled to at least one heat-generating component 210, and each heat-generating component 210 can include one or more temperature sensors T. Each cooling device 100 includes a liquid inlet 114, a liquid outlet 116, and a vapor outlet 118. In the illustrated embodiment, the liquid inlet 114 of each cooling device is coupled to a liquid supply line LS via an auxiliary pump AP, the liquid outlet 116 of each cooling device is fluidly coupled by a liquid line L to a liquid return line LR, and the vapor outlet 118 is coupled by a vapor line V to a vapor return line VR. Thus, for instance, in server S1 liquid inlet 114 is coupled by an auxiliary pump AP to liquid supply line LS, liquid outlet 116 is fluidly coupled by a liquid line L1 to liquid return line LR, and vapor outlet 118 is coupled by vapor line V1 to vapor return line VR. Server S2 has similar liquid and vapor connections as server S1.

In each server, temperature sensor T is communicatively coupled to a corresponding auxiliary pump AP, so that the amount of cooling fluid 218 delivered to liquid inlets 114 by auxiliary pumps AP can be controlled based on the temperature of the heat-generating components. In one embodiment, for instance, if a higher-than-normal temperature is registered by sensor T, the speed of the corresponding auxiliary pump can be increased to increase the flow of liquid into the corresponding cooling device 100.

Cooling unit 204 is positioned externally to IT container 202, and components within cooling unit 204 are fluidly coupled to vapor return line VR, liquid return line LR, and liquid supply line LS to close the vapor loop and the liquid loop. In one embodiment, vapor return line VR, liquid return line LR, and liquid supply line LS, or any subcombination of these, can be fluidly coupled between IT container 202 and cooling unit 204 using standard fluid connection interfaces such as blind-mating connectors, quick connect/disconnect connectors, and so on.

A condenser 212 is positioned within a housing of cooling unit 204, and cooling unit 204 also includes a reservoir of cooling fluid 218; in the illustrated embodiment, the lower part of the cooling unit's housing forms the reservoir, but in other embodiments the reservoir can be a separate tank within the housing, or can be outside the housing. Condenser 212 includes a vapor inlet 214 and a liquid outlet 216; vapor inlet 214 is fluidly coupled to vapor return line VR, and liquid outlet 216 is positioned to direct the liquid phase of cooling fluid 218 from the condenser into the reservoir.

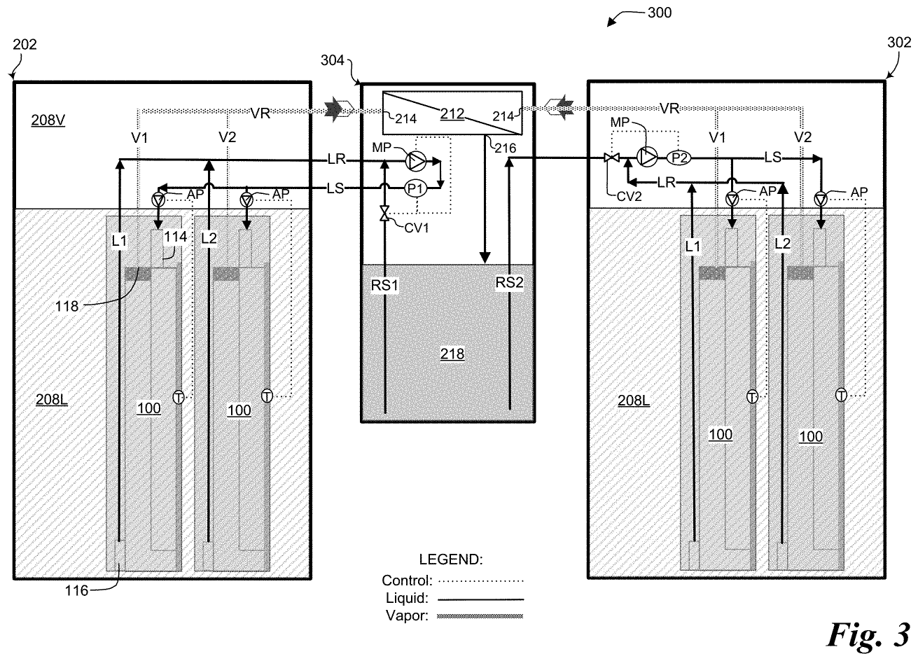

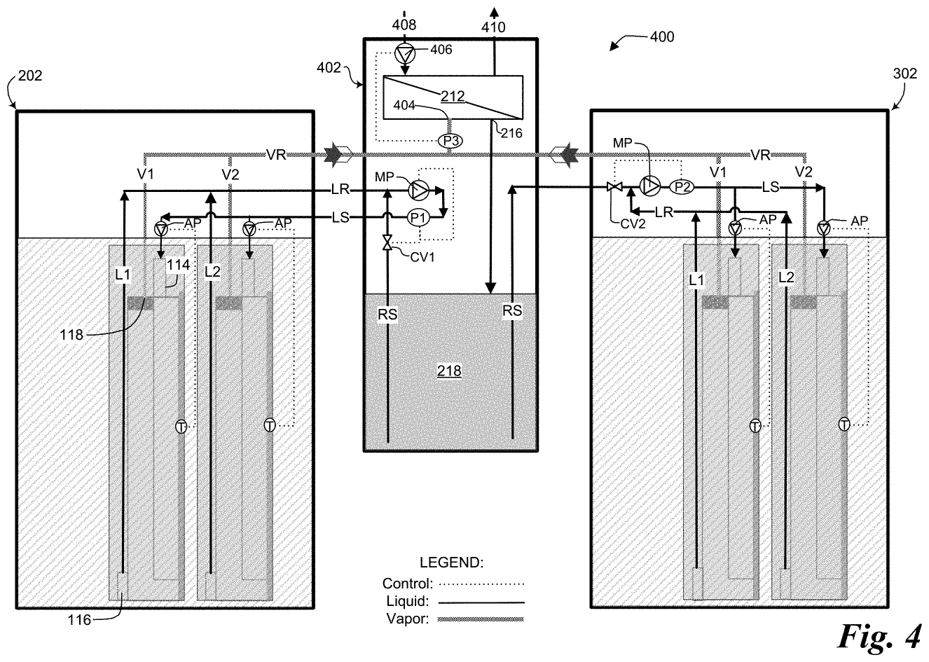

Liquid return line LR enters cooling unit 204 and is fluidly coupled to liquid supply line LS. A main pump MP is fluidly coupled into liquid return line LR, and a pressure sensor P is fluidly coupled into fluid supply line LS downstream of main pump MP. A reservoir supply line RS is fluidly coupled between the reservoir and the liquid return line LR upstream of the main pump, and a control valve CV is coupled in the reservoir supply line RS. Pressure sensor P is communicatively coupled to main pump MP and control valve CV, so that the amount of fluid flowing through the liquid loop can be controlled based on the supply pressure. For instance, if the liquid supply pressure measured by pressure sensor P drops, meaning that more liquid is needed at cooling devices 100, the speed of main pump MP and the open ratio of control valve CV can both be increased. The open ratio of control valve CV is a measure of how open the valve is. In one embodiment the open ratio can have any value between 0 and 1: an open ratio of 0 means the valve is fully closed and all flow is cut off; an open ratio of 1 means the valve is fully open and fluid flows freely through it; an open ratio of 0.5 means the valve is half open; and so on. An increase in the pump speed and valve open ratio results in liquid-phase fluid 218 being delivered from the reservoir and driven into liquid supply line LS at higher pressure and flow rate, thus delivering more liquid to cooling devices 100. In an embodiment, pressure sensor P is used for monitoring the pressure value at the liquid inlet and controlling the control valve CV and main pump MP to maintain the pressure at designed value. Maintaining the pressure value aims to ensure the fluid mass flow rate is kept at designed value. Although in the illustrated embodiment cooling unit 204 services only one IT container, in other embodiments cooling unit 204 can service multiple IT containers (see, e.g., FIGS. 3-4). In sill other embodiments, components in cooling unit 204, such as main pump MP and pressure sensor P, can service multiple liquid loops within the same or different IT containers, and similarly condenser 212 can service multiple vapor connections from the same or different IT containers.

In operation of system 200, electronic components 210 generate heat. Part of the heat from components 210 is directed into the liquid phase 208L of immersion cooling fluid 208. The heat directed into liquid phase 208L evaporates the liquid phase into vapor phase 208V, thus extracting some heat from the electronic components. Simultaneously with the heat transfer into liquid phase 208L, heat from electronic components 210 is directed into the corresponding cooling device 100. The liquid phase of two-phase cooling fluid 218, which in one embodiment can be the same as two-phase cooling fluid 208 but in other embodiments need not be, is carried in liquid supply line LS, from which it enters the cooling device's liquid chamber through liquid inlet 114. Once in the liquid chamber, the liquid phase moves downward through the liquid chamber at least partially due to gravity, absorbs heat, and partially or fully vaporizes by the time it reaches the bottom of the liquid chamber. At the bottom of the liquid chamber, whatever liquid phase fluid remains flows out of the cooling device through liquid outlet 116, while the vapor phase rises through the cooling device's vapor compartment and exists the cooling device through vapor outlet 118.

The liquid phase exiting through fluid outlet 116 is transported via a liquid line L (e.g., liquid line L1 for server S1, liquid line L2 for server S2, etc.) to liquid return line LR. Liquid return line LR then carries the liquid out of IT container 202 to cooling unit 204. At the same time, the vapor phase exiting the vapor compartment through vapor outlet 118 is transported via a vapor line V (e.g., vapor line V1 for server S1, vapor line V2 for server S2, etc.) to the vapor return line VR. Vapor return line VR then carries the liquid out of IT container 202 to cooling unit 204.

In cooling unit 204, vapor is carried by vapor return line VR to vapor inlet 214 of condenser 212. Condenser 212 extracts heat from the vapor phase, causing it to return to the liquid phase, and the liquid phase then exits the condenser through liquid outlet 216 and flows to the reservoir. Simultaneously, the liquid phase carried by liquid return line LR enters cooling unit 204, flows through the main pump MP, and is directed into liquid supply line LS, where its pressure is measured by pressure sensor P, and it is directed back out of cooling unit 204 and into IT container 202. Pressure sensor P is communicatively connected to main pump MP and control valve CV, so that if there is a pressure change in liquid supply line LS, pump MP and control valve CV can be adjusted accordingly. For instance, if pressure sensor P senses a pressure decrease, signaling increased demand for the liquid phase by cooling devices 100and/or a need for more fluid 218 from the reservoir, control valve CV can be opened so that liquid phase 218 can be drawn from the reservoir and injected into main pump MP, and main pump MP can be sped up so that the liquid returning through liquid return line LR and the additional liquid drawn from the reservoir can be delivered to cooling devices 100 at a higher pressure and flow rate. If pressure sensor P senses a pressure increase, signaling decreased demand for the liquid phase by cooling devices 100, the opposite can happen: control valve CV can be closed so that less liquid is drawn from the reservoir and injected into main pump MP, and main pump MP can be slowed so that liquid returning through liquid return line LR and liquid drawn from the reservoir can be delivered to the cooling devices at a lower pressure and flow rate.

FIG. 3 illustrates another embodiment of a two-phase cooling system 300. Cooling system 300 is in most respects similar to cooling system 200, but there are two primary differences. First, system 300 has a many-to-one correspondence between IT containers and cooling units: cooling system 300 includes multiple IT containers—two IT containers 204 and 302 in the illustrated embodiment, although other embodiments can include more than two—fluidly coupled to and serviced by a single cooling unit 304. Second, in system 300 the liquid cooling components that service IT container 302 are grouped differently than the liquid cooling components that service IT container 202. Besides illustrating that a cooling unit can service multiple IT containers, then, system 300 illustrates that the fluid handling components for the vapor and liquid cooling loops can be grouped and packaged differently in different embodiments.

System 300 includes an IT container 202, a cooling unit 304, and an additional IT container 302. IT container 202 is configured similarly to its counterpart in system 200. One or more servers S are submerged in the liquid phase 208L of two-phase cooling fluid 208, and each server has at least one heat-generating component 210 thermally coupled to a cooling device 100. Each cooling device has its liquid inlet coupled to liquid supply line LS by an auxiliary pump AP, has it liquid outlet coupled to a liquid return line LR by a liquid line L, and has its vapor outlet coupled to a vapor return line VR by a vapor line V. A temperature sensor T is communicatively coupled to each auxiliary pump AP to control its speed.

Cooling unit 304 includes the same primary components as cooling unit 204: a condenser 212 and a reservoir of cooling fluid 218. Condenser 212 includes a pair of vapor inlets 214 and a liquid outlet 216 that delivers liquid-phase cooling fluid 218 to the reservoir. In the illustrated embodiment, the lower part of the cooling unit's housing forms the reservoir, but in other embodiments the reservoir can be a separate tank within the housing, or can be outside the housing.

Cooling unit 304 is similar to cooling unit 204 in the fluid connections and components used to service IT container 202. One of condenser 212′s two vapor inlets 214 is fluidly coupled to vapor return line VR from IT container 202, and the condenser's liquid outlet 216 directs the liquid phase of two-phase cooling fluid 218 into the reservoir. Liquid return line LR enters cooling unit 304 from IT container 202 and is fluidly coupled to liquid supply line LS. A main pump MP is fluidly coupled into liquid return line LR, and a pressure sensor P1 is fluidly coupled into fluid supply line LS downstream of main pump MP. A reservoir supply line RS1 is fluidly coupled between the reservoir and the liquid return line LR upstream of the main pump, and a control valve CV1 is coupled in the reservoir supply line RS1. Pressure sensor P1 is communicatively coupled to main pump MP and control valve CV1, so that the amount of fluid flowing through the liquid loop can be controlled based on the supply pressure, as described above for system 200.

In addition to the fluid connections and components that service IT container 202, cooling unit 304 includes fluid connections and components that service IT container 302, but the fluid connections and components and their grouping and packaging are different for IT container 302 than for IT container 202. IT container 302, like IT container 202, includes a vapor return line VR that is fluidly coupled to the other of the two vapor inlets 214 of condenser 212. Liquid supply line LS enters IT container 302 from cooling unit 304 and is fluidly coupled by an auxiliary pump AP to the liquid inlet of each cooling device 100. Within cooling unit 304, liquid supply line LS is fluidly coupled to a reservoir supply line RS2. Within IT container 302, a main pump MP is fluidly coupled into liquid supply line LS, a control valve CV2 is fluidly coupled into liquid supply line LS upstream of main pump MP, and a pressure sensor is P2 fluidly coupled into liquid supply line LS downstream of main pump MP. Pressure sensor P2 is communicatively coupled to main pump MP and control valve CV2 so that the amount of fluid flowing through the liquid loop can be controlled based on the supply pressure, as described above for system 200. The liquid outlet 116 of each cooling device 100 is fluidly coupled by a liquid line L to a liquid return line LR, which in turn is fluidly coupled into liquid supply line LS between control valve CV2 and main pump MP. The vapor outlet of each cooling device 100 is coupled by a vapor line V to a vapor return line VR. In operation, system 300 operates substantially as described above for system 200. In IT container 302, then, main pump MP is used both to return liquid from the outlets of cooling devices 100 within each server as well as to draw liquid from the reservoir of cooling unit 304. The pump speed and the valve open ratio impact on the liquid flowing mass to the servers.

FIG. 4 illustrates another embodiment of a two-phase cooling system 400. Cooling system 400 is in most respects similar to cooling system 300: it includes two IT containers 202 and 302, both of which are coupled to a cooling unit 404. IT containers 202 and 302 are both configured substantially as they are in system 300. The primary difference between systems 300 and 400 is that in system 400 cooling unit 402 is configured differently than cooling unit 304, with additional components for control of condenser 212.

In cooling unit 402, condenser 212 has a single vapor inlet 404 to which vapor return lines VR from both IT containers 202 and 302 are fluidly coupled. A pressure sensor P3 is coupled between the vapor return lines VR and vapor inlet 404. Condenser 212 also includes an external coolant inlet 408 with an external coolant pump 406 coupled therein, and an external coolant outlet 410. Pressure sensor P3 is communicatively coupled to external coolant pump 406, so that the pump's speed can be controlled based on the pressure measured by sensor P3.

System 400 operates substantially the same way as system 300, with the addition of controlled operation of condenser 212. Sensor P3 senses the vapor pressure in vapor return lines VR from both IT containers 202 and 302. If the sensed pressure is high, meaning that a lot of vapor is entering cooling unit 402 through vapor return lines VR, the speed of pump 406 can be increased, thereby increasing the flow rate of external coolant into condenser 212 and increasing the condenser's rate of condensation. An increased condensation rate in condenser 212 increases the outflow of the liquid phase of two-phase cooling fluid 218 through fluid outlet 216 into the fluid reservoir. Conversely, if sensor P3 senses a low pressure, meaning that less vapor is entering cooling unit 402 through vapor return lines VR, the speed of pump 406 can be decreased to decrease the flow rate of external coolant into condenser 212, thereby decreasing the condenser's condensation rate and decreasing the outflow of the liquid phase of two-phase cooling fluid 218 through fluid outlet 216 into the fluid reservoir. Thus, P1 controls the main pump MP and control valve CV1 in cooling unit 402 to ensure fluid flow into the IT containers connected to it; P2 controls the main pump and the control valve for controlling the fluid mass flow rate of its own recirculation loop in IT container 302; and P3 controls the external cooling source based on the vapor pressure at the inlet of condenser 212.

Other embodiments are possible besides the ones described above. For instance:
The immersion tank can be designed in different configurations.
The solution can be implemented in different server configurations and IT systems.
More control features can be added to the present solution to allow further improvement and optimization.

The above description of embodiments is not intended to be exhaustive or to limit the invention to the described forms. Specific embodiments of, and examples for, the invention are described herein for illustrative purposes, but various modifications are possible.

What is claimed is:

1. An cooling device comprising:
a housing enclosing an internal volume, the housing including at least a heat transfer contact surface adapted to be thermally coupled to a heat-generating electronic component;
a partition positioned within the internal volume, wherein the partition divides the internal volume into a liquid compartment and a vapor compartment, and wherein the partition has a gap therein to allow fluid movement between the liquid compartment and the vapor compartment;
a liquid inlet fluidly coupled to the liquid compartment;
a liquid outlet fluidly coupled to the vapor compartment; and
a vapor outlet fluidly coupled to with the vapor compartment.

2. The cooling device of claim 1 wherein the liquid inlet is at or near the top of the liquid compartment, the vapor outlet is at or near the top of the vapor compartment, and the liquid outlet is at or near the bottom of the vapor compartment.

3. The cooling device of claim 2 wherein the gap in the partition is at or near the bottom of the internal volume.

4. The cooling device of claim 1 wherein the heat transfer contact surface is vertically oriented.

5. The cooling device of claim 1, further comprising a plurality of heat transfer fins positioned in the liquid compartment and thermally coupled to the heat transfer contact surface.

6. The cooling device of claim 1, further comprising one or more filters positioned in the vapor compartment.

7. A cooling system for information technology (IT) cluster comprising:
an IT container adapted to house one or more servers submerged in an immersion cooling fluid;
one or more cooling devices, each cooling device adapted to be coupled to a heat-generating electronic component in at least one of the servers, and each cooling device including:
a housing enclosing an internal volume, the housing including at least a heat transfer contact surface adapted to be thermally coupled to a heat-generating electronic component,
a partition positioned within the internal volume, wherein the partition divides the internal volume into a liquid compartment and a vapor compartment, and wherein the partition has a gap therein to allow fluid movement between the liquid compartment and the vapor compartment,
a liquid inlet fluidly coupled to the liquid compartment,
a liquid outlet fluidly coupled to the vapor compartment, and
a vapor outlet fluidly coupled to with the vapor compartment;
a liquid loop to circulate a liquid phase of a two-phase cooling fluid, the liquid loop including:
a liquid supply line fluidly coupled to the liquid inlet of each cooling device;
a liquid return line fluidly coupled to the liquid supply line and to the liquid outlet of each cooling device; and
a vapor return line coupled to the vapor outlet of each cooling device to transport a vapor phase of the two-phase cooling fluid exiting the vapor outlet.

8. The IT cooling system of claim 7, further comprising an auxiliary pump fluidly coupled between the liquid supply line and the liquid inlet of at least one of the one or more cooling devices.

9. The IT cooling system of claim 8, further comprising a temperature sensor thermally coupled to each heat-generating electronic component and communicatively coupled to a corresponding auxiliary pump, wherein each auxiliary pump is controlled based on the output of the coupled temperature sensor.

10. The IT cooling system of claim 7, further comprising a cooling unit separate from the IT container, the cooling unit including:
a condenser having a vapor inlet and a liquid outlet, the vapor return line being fluidly coupled to the vapor inlet of the condenser;
a reservoir coupled to the liquid outlet of the condenser to hold the liquid phase of the two-phase cooling fluid;
a reservoir line that fluidly couples the reservoir to the liquid loop;
a fluid connection that couples the liquid return line to the liquid supply line;
a main pump coupled in the liquid loop to drive flow through the liquid loop; and
a control valve coupled into the reservoir line.

11. The IT cooling system of claim 10 wherein the cooling unit further comprises:
an external coolant inlet and an external coolant outlet fluidly coupled to the condenser, the external coolant inlet having an external coolant pump coupled therein;
a pressure sensor fluidly coupled to the vapor inlet of the condenser and communicatively coupled to the external coolant pump.

12. The IT cooling system of claim 10 wherein the main pump is coupled in the liquid return line and the liquid supply line is coupled to an outlet of the main pump.

13. The IT cooling system of claim 12, further comprising a pressure sensor fluidly coupled into the liquid supply line downstream of the main pump, the pressure sensor being communicatively coupled to the main pump and the control valve so that operation of the main pump and the control valve can be adjusted based on the output of the pressure sensor.

14. An information technology (IT) cooling system comprising:
an IT container adapted to house one or more servers submerged in an immersion cooling fluid;
one or more cooling devices, each cooling device adapted to be coupled to a heat-generating electronic component in at least one of the servers, and each cooling device including:
a housing enclosing an internal volume, the housing including at least a heat transfer contact surface adapted to be thermally coupled to a heat-generating electronic component,
a partition positioned within the internal volume, wherein the partition divides the internal volume into a liquid compartment and a vapor compartment, and wherein the partition has a gap therein to allow fluid movement between the liquid compartment and the vapor compartment,
a liquid inlet fluidly coupled to the liquid compartment,
a liquid outlet fluidly coupled to the vapor compartment, and
a vapor outlet fluidly coupled to with the vapor compartment;
a liquid loop to circulate a liquid phase of a two-phase cooling fluid, the liquid loop including:
a liquid supply line fluidly coupled to the liquid inlet of each cooling device,
a liquid return line fluidly coupled to the liquid supply line and to the liquid outlet of each cooling device,
a main pump coupled in the liquid loop to drive flow through the liquid loop, and
a control valve coupled into the liquid supply line;
a vapor return line coupled to the vapor outlet of each cooling device to transport a vapor phase of the two-phase cooling fluid exiting the vapor outlet;

15. The IT cooling system of claim 14, further comprising an auxiliary pump fluidly coupled between the liquid supply line and the liquid inlet of at least one of the one or more cooling devices.

16. The IT cooling system of claim 15, further comprising a temperature sensor thermally coupled to each heat-generating electronic component and communicatively coupled to a corresponding auxiliary pump, wherein each auxiliary pump is controlled based on the output of the coupled temperature sensor.

17. The IT cooling system of claim 14, further comprising a cooling unit separate from the IT container, the cooling unit including:
a condenser having a vapor inlet and a liquid outlet, the vapor return line being fluidly coupled to the vapor inlet of the condenser;
a reservoir coupled to the liquid outlet of the condenser to hold the liquid phase of the two-phase cooling fluid; and
a reservoir line that fluidly couples the reservoir to the liquid supply line upstream of the control valve.

18. The IT cooling system of claim 17 wherein the cooling unit further comprises:
an external coolant inlet and an external coolant outlet fluidly coupled to the condenser, the external coolant inlet having an external coolant pump coupled therein;
a pressure sensor fluidly coupled to the vapor inlet of the condenser and communicatively coupled to the external coolant pump.

19. The IT cooling system of claim 14 wherein the main pump is coupled in the liquid return line and the liquid supply line is coupled to an outlet of the main pump.

20. The IT cooling system of claim 19, further comprising a pressure sensor fluidly coupled into the liquid supply line downstream of the main pump, the pressure sensor being communicatively coupled to the main pump and the control valve so that operation of the main pump and the control valve can be adjusted based on the output of the pressure sensor.
